(19) United States
(12) Patent Application Publication
(10) Pub. No.: US 2011/0290309 A1
(43) Pub. Date: Dec. 1, 2011

(54) Solar Cell and Method for Manufacturing the Same

(76) Inventor: Jung Hyun LEE, Suwon-si (KR)

(21) Appl. No.: 13/114,520

(22) Filed: May 24, 2011

(30) Foreign Application Priority Data
May 27, 2010 (KR) 10-2010-0049713

(51) Int. Cl. H01L 31/0352; H01L 31/18; H01L 31/06

(52) U.S. Cl. 136/255; 438/87; 257/E31.032

(57) ABSTRACT

Disclosed is a solar cell and a method for manufacturing the same, which facilitates to improve cell efficiency by smoothly drifting carrier such as hole or electron generated in a semiconductor wafer to first and second electrodes, the solar cell comprising a semiconductor wafer having a predetermined polarity; a first semiconductor layer on one surface of the semiconductor wafer; a first transparent conductive layer on the first semiconductor layer; a first electrode on the first transparent conductive layer; a second semiconductor layer on the other surface of the semiconductor wafer, wherein the second semiconductor layer is different in polarity from the first semiconductor layer; a second transparent conductive layer on the second semiconductor layer; a second electrode on the second transparent conductive layer; and at least one of first and second auxiliary layers, wherein the first auxiliary layer is formed between the first semiconductor layer and the first transparent conductive layer so as to smoothly drift carriers generated in the semiconductor wafer to the first transparent conductive layer, and the second auxiliary layer is formed between the second semiconductor layer and the second transparent conductive layer so as to smoothly drift carriers generated in the semiconductor wafer to the second transparent conductive layer.

### CROSS REFERENCE TO RELATED APPLICATIONS

This application claims the benefit of the Korean Patent Application No. P2010-0049713 filed on May 27, 2010, which is hereby incorporated by reference as if fully set forth herein.

### BACKGROUND OF THE INVENTION

1. Field of the Invention

The present invention relates to a solar cell.

2. Discussion of the Related Art

A solar cell with a property of semiconductor converts a light energy into an electric energy.

The solar cell is formed in a PN junction structure where a positive (P)-type semiconductor makes a junction with a negative (N)-type semiconductor. When solar ray is incident on the solar cell with the PN-junction structure, hole (+) and electron (−) are generated in the semiconductor owing to the energy of the solar ray. By an electric field generated in the PN junction, the hole (+) is drifted toward the P-type semiconductor and the electron (−) is drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. The thin film type solar cell is advantageous in that its manufacturing cost is relatively lower than that of the wafer type solar cell.

There has been proposed a related art solar cell obtained by combining the wafer type solar cell with the thin film type solar cell. Hereinafter, a related art solar cell will be described with reference to the accompanying drawings.

FIG. 1 is a cross section view illustrating a related art solar cell.

As shown in FIG. 1, the related art solar cell includes a semiconductor wafer 10, a first semiconductor layer 20, a first electrode 30, a second semiconductor layer 40, and a second electrode 50.

The first semiconductor layer 20 is formed in a thin-film type on an upper surface of the semiconductor wafer 10; and the second semiconductor layer 40 is formed in a thin-film type on a lower surface of the semiconductor wafer 10. Thus, a PN-junction structure can be obtained by combining the semiconductor wafer 10, the first semiconductor layer 20, and the second semiconductor layer 40.

The first electrode 30 is formed on the first semiconductor layer 20, and the second electrode 50 is formed on the second semiconductor layer 40, whereby the first and second electrodes 30 and 50 respectively function as (+) and (−) polarities of the solar cell.

When a solar ray is incident on the related art solar cell, carrier such as hole or electron is generated in the semiconductor wafer 10, and the generated carrier is drifted to the first electrode 30 via the first semiconductor layer 20, and simultaneously drifted to the second electrode 50 via the second semiconductor layer 40.

However, in case of the related art solar cell, the carriers generated in the semiconductor wafer 10 do not smoothly drift to the first or second electrode 30 or 50, thereby lowering cell efficiency due to the deteriorated drift mobility of the carriers.

### SUMMARY OF THE INVENTION

Accordingly, the present invention is directed to a solar cell and a method for manufacturing the same that substantially obviates one or more problems due to limitations and disadvantages of the related art.

An object of the present invention is to provide a solar cell and a method for manufacturing the same, which facilitates to improve cell efficiency by smoothly drifting carrier such as hole or electron generated in a semiconductor wafer to first and second electrodes.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a solar cell comprising: a semiconductor wafer having a predetermined polarity; a first semiconductor layer on one surface of the semiconductor wafer; a first transparent conductive layer on the first semiconductor layer; a first electrode on the first transparent conductive layer; a second semiconductor layer on the other surface of the semiconductor wafer, wherein the second semiconductor layer is different in polarity from the first semiconductor layer; a second transparent conductive layer on the second semiconductor layer; a second electrode on the second transparent conductive layer; and at least one of first and second auxiliary layers, wherein the first auxiliary layer is formed between the first semiconductor layer and the first transparent conductive layer so as to smoothly drift carriers generated in the semiconductor wafer to the first transparent conductive layer, and the second auxiliary layer is formed between the second semiconductor layer and the second transparent conductive layer so as to smoothly drift carriers generated in the semiconductor wafer to the second transparent conductive layer.

In another aspect of the present invention, a method for manufacturing a solar cell comprises forming a first semiconductor layer on one surface of a semiconductor wafer having a predetermined polarity; forming a first transparent conductive layer on the first semiconductor layer; forming a first electrode on the first transparent conductive layer; forming a second semiconductor layer on the other surface of the semiconductor wafer, wherein the second semiconductor layer is different in polarity from the first semiconductor layer; forming a second transparent conductive layer on the second semiconductor layer; forming a second electrode on the second transparent conductive layer; and forming at least one of first and second auxiliary layers, wherein the first auxiliary layer is formed between the first semiconductor layer and the first transparent conductive layer so as to smoothly drift carriers generated in the semiconductor wafer to the first transparent conductive layer, and the second auxiliary layer is formed between the second semiconductor layer and the second transparent conductive layer so as to smoothly drift carriers generated in the semiconductor wafer to the second transparent conductive layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross section view illustrating a related art solar cell;

FIG. 2 is a cross section view illustrating a solar cell according to the first embodiment of the present invention;

FIG. 3 is a cross section view illustrating a solar cell according to the second embodiment of the present invention;

FIG. 4 is a cross section view illustrating a solar cell according to the third embodiment of the present invention;

FIGS. 5a to 5H are cross section views illustrating a method for manufacturing a solar cell according to an embodiment of the present invention;

FIGS. 6A to 6D are cross section views illustrating a method for manufacturing a solar cell according to another embodiment of the present invention; and

FIGS. 7A to 7D are cross section views illustrating a method for manufacturing a solar cell according to another embodiment of the present invention.

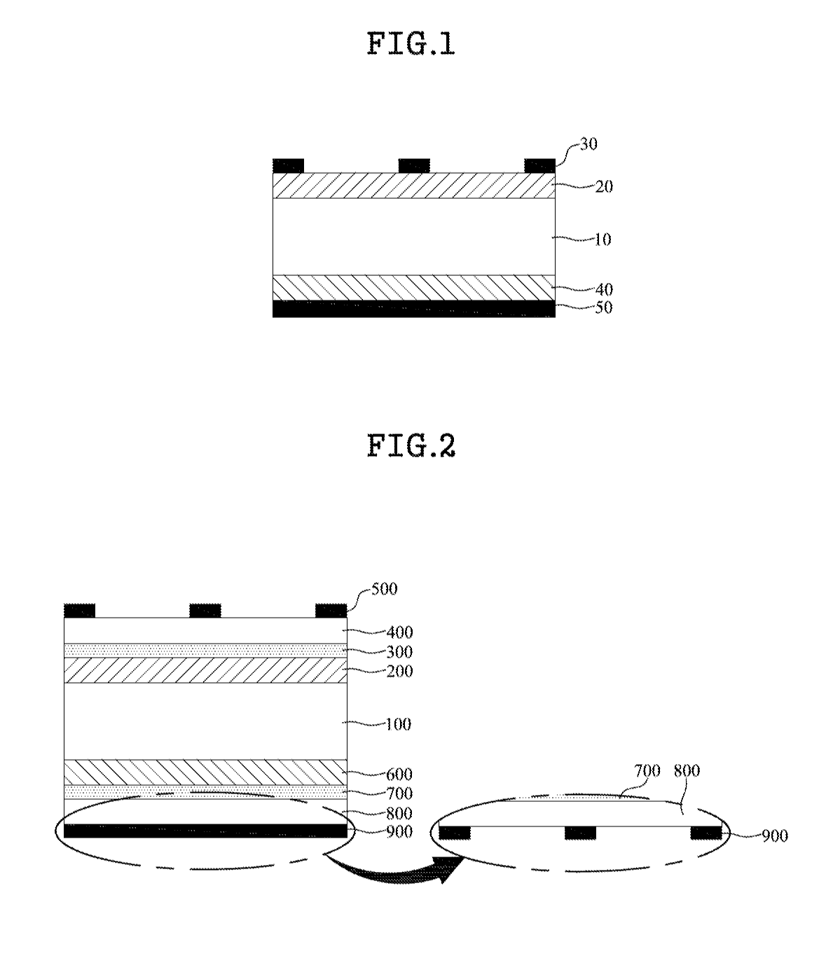

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a solar cell according to the present invention and a method for manufacturing the same will be described with reference to the accompanying drawings.

FIG. 2 is a cross section view illustrating a solar cell according to the first embodiment of the present invention.

As shown in FIG. 2, the solar cell according to the first embodiment of the present invention comprises a semiconductor wafer 100, a first semiconductor layer 200, a first auxiliary layer 300, a first transparent conductive layer 400, a first electrode 500, a second semiconductor layer 600, a second auxiliary layer 700, a second transparent conductive layer 800, and a second electrode 900.

The semiconductor wafer 100 may be formed of a silicon wafer, and more particularly, N-type silicon wafer or P-type silicon wafer. The semiconductor wafer 100 is identical in polarity to any one of the first and second semiconductor layers 200 and 600.

The first semiconductor layer 200 is formed in a thin-film type on an upper surface of the semiconductor wafer 100. The first semiconductor layer 200, together with the semiconductor wafer 100, can make a PN junction. Thus, if the semiconductor wafer 100 is formed of the N-type silicon wafer, the first semiconductor layer 200 may be formed of a P-type semiconductor layer. Especially, the first semiconductor layer 200 may be formed of P-type amorphous silicon doped with group III elements such as boron (B).

Because a drift mobility of the hole is less than a drift mobility of the electron, the P-type semiconductor layer is provided adjacent to a light-incidence face, to thereby maximize the efficiency in collection of the hole by the incident solar ray. Thus, it is preferable that the first semiconductor layer 200 adjacent to the light-incidence face be formed of the P-type semiconductor layer.

The first auxiliary layer 300 is formed between the first semiconductor layer 200 and the first transparent conductive layer 400. The first auxiliary layer 300 makes the carrier generated in the semiconductor wafer 100, for example, the hole smoothly drift to the first transparent conductive layer 400.

In more detail, if the first semiconductor layer 200 is formed of the P-type semiconductor layer, the first auxiliary layer 300 is formed of a negative (−) polarity material layer so as to attract the hole generated in the semiconductor wafer 100, preferably. Especially, the negative (−) material layer may be formed of oxygen-rich oxide, for example, oxide including Group III elements such as Al₂O₃, Ga₂O₃, or In₂O₃.

The first transparent conductive layer 400 collects the carrier generated in the semiconductor wafer 100, for example, collects the hole; and then drifts the collected hole to the first electrode 500.

The first transparent conductive layer 400 may be formed of a transparent conductive material capable of transmitting a large amount of solar ray, for example, ITO (Indium Tin Oxide), ZnOH, ZnO:B, ZnO:Al, SnO₂, or SnO₂:F.

The first electrode 500 is formed on the first transparent conductive layer 400, which forms the forefront surface of the solar cell. Thus, the first electrode 500 is formed in a predetermined pattern enabling to transmit the solar ray to the inside of the solar cell, preferably.

The first electrode 500 may be formed of a metal material with good conductivity, for example, Ag, Al, Ag+Al, Ag+Mg, Ag+Mn, Ag+Sb, Ag+Zn, Ag+Mo, Ag+Ni, Ag+Cu, or Ag+Al+Zn.

The second semiconductor layer 600 is formed in a thin-film type on a lower surface of the semiconductor wafer 100. The second semiconductor layer 600 is different in polarity from the first semiconductor layer 200. If the first semiconductor layer 200 is formed of the P-type semiconductor layer doped with Group III elements such as boron (B), the second semiconductor layer 600 is formed of the N-type semiconductor layer doped with Group V elements such as phosphorus (P). Especially, the second semiconductor layer 600 may be formed of N-type amorphous silicon.

The second auxiliary layer 700 is formed between the second semiconductor layer 600 and the second transparent conductive layer 800. The second auxiliary layer 700 makes the carrier generated in the semiconductor wafer 100, for example, the electron smoothly drift to the second transparent conductive layer 800.

In more detail, if the second semiconductor layer 600 is formed of the N-type semiconductor layer, the second auxiliary layer 700 is formed of a positive (+) polarity material layer so as to attract the electron generated in the semiconductor wafer 100, preferably. Especially, the positive (+) material layer may be formed of oxygen-deficient oxide, for example, oxide including Group IV elements such as SiOₓ, TiOₓ, ZrOₓ, or HfOₓ, where x is between 1 and 2 (e.g., between 1.8 and 1.99).

The second transparent conductive layer 800 collects the carrier generated in the semiconductor wafer 100, for example, collects the electron; and then drifts the collected electron to the second electrode 900.

The second transparent conductive layer 800 may be formed of a transparent conductive material, for example, ITO (Indium Tin Oxide), ZnOH, ZnO:B, ZnO:Al, SnO₂, or SnO₂:F. In the present invention, the second transparent conductive layer 800 may be formed of a compound including ZnO, for example, ZnOH, ZnO:B, or ZnO:Al, instead of ITO.

The ITO is formed by a physical vapor deposition method such as a sputtering method. If the second transparent conductive layer 800 is formed by the physical vapor deposition method, the second transparent conductive layer 800 might be not uniform, and also have a defect such as a void therein. If the defect such as the void occurs in the second transparent conductive layer 800, a contact area between the second transparent conductive layer 800 and the second electrode 900 is decreased so that it is difficult to realize the smooth collection and drift of the carrier.

Especially, if the semiconductor wafer 100 has an uneven surface made by a texturing process, the second transparent conductive layer 800 also has an uneven surface. When an ITO layer is formed by the physical vapor deposition method such as the sputtering method, the defect such as the void may be increased in the ITO layer. Instead of using ITO, the second transparent conductive layer 800 is formed of the material suitable for a chemical vapor deposition method such as MOCVD (Metal Organic Chemical Vapor Deposition), thereby maximizing the smooth collection and drift of the carrier. The layer formed by the chemical vapor deposition method such as MOCVD becomes more uniform than the layer formed by the physical vapor deposition method such as the sputtering method. Similarly, the first transparent conductive layer 400 may be formed of a compound including ZnO, for example, ZnOH, ZnO:B, or ZnO:Al, instead of ITO.

The second electrode 900 is formed on the second transparent conductive layer 800. Since the second electrode 900 is formed in the rearmost surface of the solar cell, the second electrode 900 may be formed on an entire surface of the second transparent conductive layer 800. In order to make the reflected solar ray incident via the rear surface of the solar cell, the second electrode 900 may be patterned as shown in an arrow of FIG. 2.

Like the first electrode 500, the second electrode 900 may be formed of a metal material, for example, Ag, Al, Ag+Al, Ag+Mg, Ag+Mn, Ag+Sb, Ag+Zn, Ag+Mo, Ag+Ni, Ag+Cu, or Ag+Al+Zn.

As explained above, the carrier, generated in the semiconductor wafer 100, is collected in the first transparent conductive layer 400 and then drifted to the first electrode 500; and simultaneously is collected in the second transparent conductive layer 800 and then drifted to the second electrode 900, whereby the drift mobility of the carrier is more increased in comparison with the related art.

If the first transparent conductive layer 400 is directly formed on the first semiconductor layer 200 without forming the first auxiliary layer 300 therebetween, it might be difficult to drift the carrier such as the hole from the first semiconductor layer 200 to the first transparent conductive layer 400 due to an energy band gap between the first semiconductor layer 200 and the first transparent conductive layer 400. According to the present invention, since the first auxiliary layer 300, which is formed of the negative (−) polarity material layer so as to attract the hole, is provided between the first semiconductor layer 200 and the first transparent conductive layer 400, the hole is easily drifted from the first semiconductor layer 200 to the first transparent conductive layer 400.

Similarly, if the second transparent conductive layer 800 is directly formed on the second semiconductor layer 600 without forming the second auxiliary layer 700 therebetween, it might be difficult to drift the carrier such as the electron from the second semiconductor layer 600 to the second transparent conductive layer 800 due to an energy band gap between the second semiconductor layer 600 and the second transparent conductive layer 800. According to the present invention, since the second auxiliary layer 700, which is formed of the positive (+) polarity material so as to attract the electron, is provided between the second semiconductor layer 600 and the second transparent conductive layer 800, the electron is easily drifted from the second semiconductor layer 600 to the second transparent conductive layer 800.

Preferably, a thickness of each of the first and second auxiliary layers 300 and 700 is not more than 3 nm. If the thickness of each of the first and second auxiliary layers 300 and 700 is more than 3 nm, the drift mobility of the hole or electron might be rather deteriorated.

FIG. 2 illustrates that both the first and second auxiliary layers 300 and 700 are formed. However, it is possible to form any one of the first and second auxiliary layers 300 and 700.

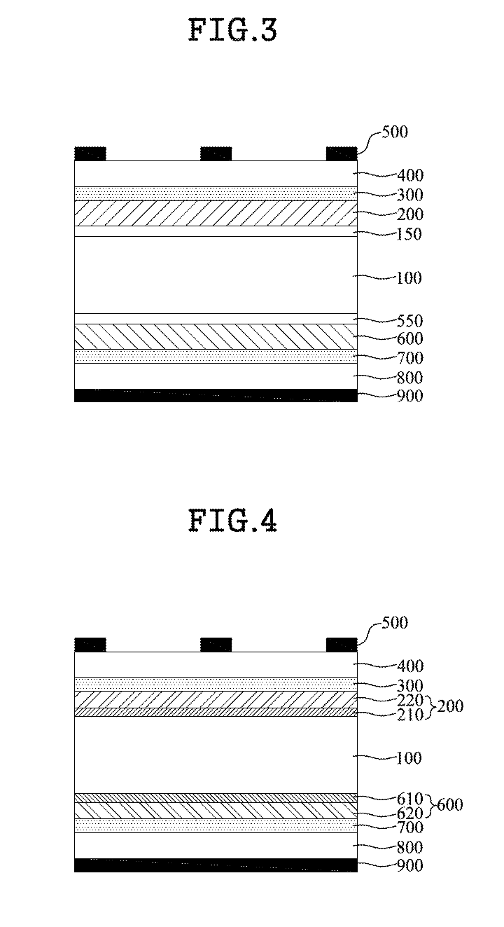

FIG. 3 is a cross section view illustrating a solar cell according to the second embodiment of the present invention. Except that a first intrinsic semiconductor layer 150 is additionally formed between a semiconductor wafer 100 and a first semiconductor layer 200, and a second intrinsic semiconductor layer 550 is additionally formed between the semiconductor wafer 100 and a second semiconductor layer 600; the solar cell of the second embodiment shown in FIG. 3 is identical in structure to the solar cell of the first embodiment shown in FIG. 2. Thus, the same reference numbers will be used throughout the drawings to refer to the same or like parts, and a detailed explanation for the same parts will be omitted.

If the first semiconductor layer 200 or second semiconductor layer 600 is formed on the surface of the semiconductor wafer 100 by the use of highly-concentrated dopant gas, the highly-concentrated dopant gas may cause defects in the surface of the semiconductor wafer 100.

In case of the second embodiment of the present invention shown in FIG. 3, the first intrinsic semiconductor layer 150 is formed on the upper surface of the semiconductor wafer 100, and then the first semiconductor layer 200 is formed on the first intrinsic semiconductor layer 150, to thereby prevent the defects from occurring in the upper surface of the semiconductor wafer 100. Also, the second intrinsic semiconductor layer 550 is formed on the lower surface of the semiconductor wafer 100, and then the second semiconductor layer 600 is formed on the second intrinsic semiconductor layer 500, to thereby prevent the defects from occurring in the lower surface of the semiconductor wafer 100.

FIG. 3 illustrates that both the first and second intrinsic semiconductor layers 150 and 550 are formed. However, it is possible to form any one of the first and second intrinsic semiconductor layers 150 and 550.

FIG. 4 is a cross section view illustrating a solar cell according to the third embodiment of the present invention. Except that first and semiconductor layers 200 and 600 are changed in structure, the solar cell of the third embodiment shown in FIG. 4 is identical in structure to the solar cell of the first embodiment shown in FIG. 2. Thus, the same reference numbers will be used throughout the drawings to refer to the same or like parts, and a detailed explanation for the same parts will be omitted.

As shown in FIG. 4, in case of the solar cell according to the third embodiment of the present invention, the first semiconductor layer 200 comprises a first lightly-doped semiconductor layer 210 on the upper surface of the semiconductor wafer 100, and a first highly-doped semiconductor layer 220 on the first lightly-doped semiconductor layer 210.

Also, the second semiconductor layer 600 comprises a second lightly-doped semiconductor layer 610 on the lower surface of the semiconductor wafer 100, and a second highly-doped semiconductor layer 620 on the second lightly-doped semiconductor layer 610.

In this case, the lightly-doped and highly-doped layers are relative concepts. That is, it means that the dopant concentration of the first lightly-doped semiconductor layer 210 is relatively lower than the dopant concentration of the first highly-doped semiconductor layer 220.

The first lightly-doped semiconductor layer 210 and the second lightly-doped semiconductor layer 610 respectively have the same function as the first and second intrinsic semiconductor layers 150 and 550 in the solar cell of the second embodiment shown in FIG. 3.

That is, the first lightly-doped semiconductor layer 210 is firstly formed on the upper surface of the semiconductor wafer 100, and then the first highly-doped semiconductor layer 220 is formed thereon, to thereby prevent the defects from occurring in the upper surface of the semiconductor wafer 100. Also, the second lightly-doped semiconductor layer 610 is firstly formed on the lower surface of the semiconductor wafer 100, and then the second highly-doped semiconductor layer 620 is formed thereon, to thereby prevent the defects from occurring in the lower surface of the semiconductor wafer 100.

Thus, the dopant concentration of the first lightly-doped semiconductor layer 210 and second lightly-doped semiconductor layer 610 is adjusted to an appropriate level capable of preventing the defects from occurring in the surface of the semiconductor wafer 100, preferably.

Productivity of the solar cell according to the third embodiment of the present invention shown in FIG. 4 is higher than productivity of the solar cell according to the second embodiment of the present invention shown in FIG. 3. That is, the solar cell according to the second embodiment of the present invention shown in FIG. 3 may be lowered in productivity because of an additional provision of a deposition apparatus for forming the first and second intrinsic semiconductor layers 150 and 550, and a complicated process. However, in case of the solar cell of the third embodiment shown in FIG. 4, there is no requirement for the additional provision of the deposition apparatus because the first lightly-doped semiconductor layer 210 and first highly-doped semiconductor layer 220 are sequentially formed inside one chamber, and the second lightly-doped semiconductor layer 610 and second highly-doped semiconductor layer 620 are sequentially formed inside one chamber.

FIG. 4 illustrates that the first semiconductor layer 200 comprises the first lightly-doped semiconductor layer 210 and the first highly-doped semiconductor layer 220, and the second semiconductor layer 600 comprises the second lightly-doped semiconductor layer 610 and the second highly-doped semiconductor layer 620. However, any one of the first and second semiconductor layers 200 and 600 may comprise the lightly-doped semiconductor layer and the highly-doped semiconductor layer.

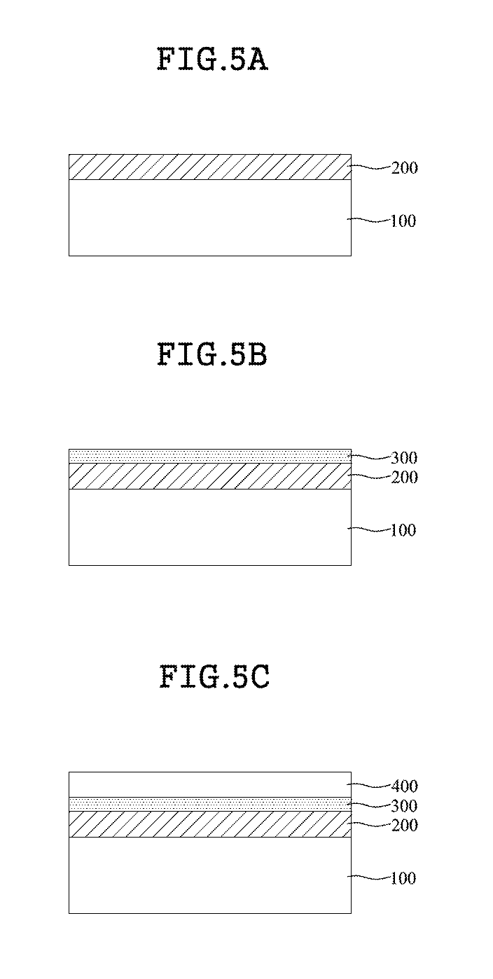

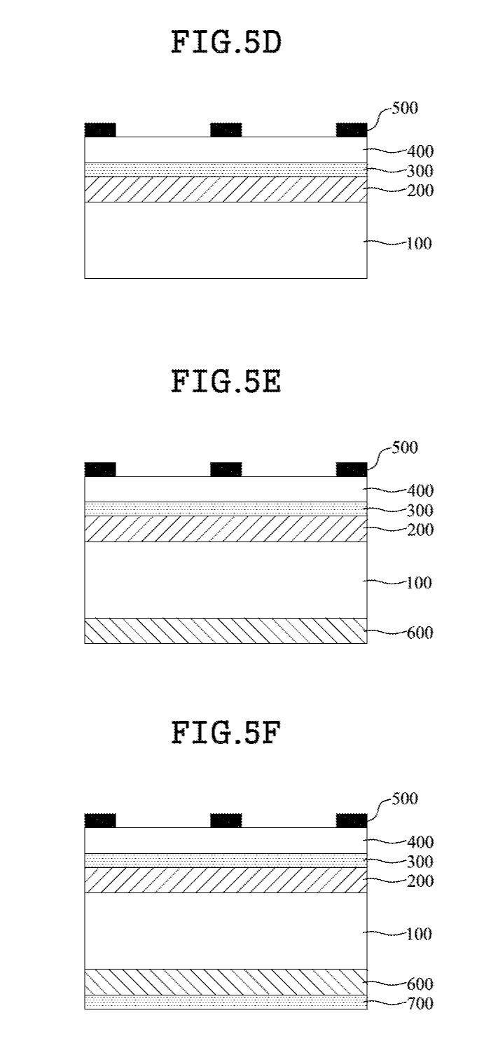

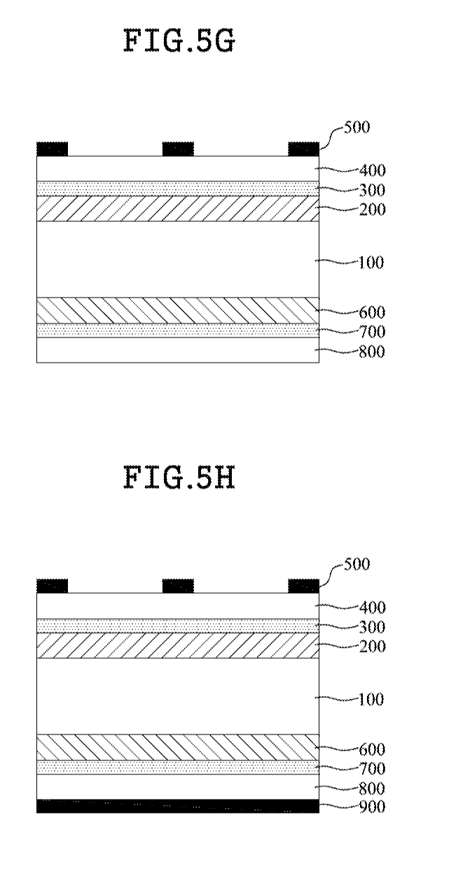

FIGS. 5A to 5H are cross section views illustrating a method for manufacturing a solar cell according to an embodiment of the present invention, which illustrate a method for manufacturing the solar cell according to the first embodiment of the present invention shown in FIG. 2.

First, as shown in FIG. 5A, the first semiconductor layer 200 is formed on the upper surface of the semiconductor wafer 100.

The semiconductor wafer 100 may be formed of an N-type silicon wafer.

A process for forming the first semiconductor layer 200 may comprise forming a P-type semiconductor layer such as a P-type amorphous silicon layer on the semiconductor wafer 100 by PECVD (Plasma Enhanced Chemical Vapor Deposition).

Then, as shown in FIG. 5B, the first auxiliary layer 300 is formed on the first semiconductor layer 200.

A process for forming the first auxiliary layer 300 may comprise forming the negative (−) polarity material layer, for example, oxygen-rich oxide layer including Group III elements such as Al₂O₃, Ga₂O₃, or In₂O₃ on the first semiconductor layer 200 by MOCVD (Metal Organic Chemical Vapor Deposition).

As shown in FIG. 5C, the first transparent conductive layer 400 is formed on the first auxiliary layer 300.

A process for forming the first transparent conductive layer 400 may comprise forming a transparent conductive layer of ITO (Indium Tin Oxide), ZnOH, ZnO:B, ZnO:Al, SnO₂, or SnO₂:F by sputtering or MOCVD (Metal Organic Chemical Vapor Deposition).

As shown in FIG. 5D, the first electrode 500 is formed on the first transparent conductive layer 400.

The first electrode 500 may be formed in a predetermined pattern enabling to transmit the solar ray to the inside of the solar cell.

The first electrode 500 may be formed of a metal material such as Ag, Al, Ag+Al, Ag+Mg, Ag+Mn, Ag+Sb, Ag+Zn, Ag+Mo, Ag+Ni, Ag+Cu, or Ag+Al+Zn by a printing process. In this case, the printing process may be a screen printing method, an inkjet printing method, a gravure printing method, a gravure offset printing method, a reverse printing method, a flexo printing method, or a microcontact printing method. In case of the screen printing method, ink is coated onto a screen, and then the squeegee is moved on the screen coated with the ink while being pressed-down, whereby the ink is printed through a mesh of the screen. The inkjet printing method is a printing method in which tiny ink drops collide with a substrate. The gravure printing method is carried out by removing ink from an ink non-coated portion with a flat surface by the use of doctor blade, and transferring ink from an etched ink-coated portion with a hollow shape to a substrate. The gravure offset printing method is carried out by transferring ink from a printing plate to a blanket, and again transferring ink from the blanket to a substrate. The reverse printing method is a printing method using ink as a solvent. The flexo printing method is a printing method which uses ink coated onto a relief portion. The microcontact printing method is an imprinting method which uses a stamp with a desired material.

If using the printing process, the plurality of first electrodes 500 may be patterned at fixed intervals by one process, thereby simplifying the manufacturing process.

As shown in FIG. 5E, the second semiconductor layer 600 is formed on the lower surface of the semiconductor wafer 100.

A process for forming the second semiconductor layer 600 may comprise forming an N-type semiconductor layer such as an N-type amorphous silicon layer on the semiconductor wafer 100 by PECVD (Plasma Enhanced Chemical Vapor Deposition).

As shown in FIG. 5F, the second auxiliary layer 700 is formed on the second semiconductor layer 600.

A process for forming the second auxiliary layer 700 may comprise forming the positive (+) polarity material layer, for example, oxygen-deficient oxide layer including Group IV elements such as SiOₓ, TiOₓ, ZrOₓ, or HfOₓ on the second semiconductor layer 600 by MOCVD (Metal Organic Chemical Vapor Deposition).

As shown in FIG. 5G, the second transparent conductive layer 800 is formed on the second auxiliary layer 700.

A process for forming the second transparent conductive layer 800 may comprise forming a transparent conductive material layer such as ITO (Indium Tin Oxide), ZnOH, ZnO:B, ZnO:Al, SnO₂, or SnO₂:F by sputtering or MOCVD (Metal Organic Chemical Vapor Deposition).

As mentioned above, if the second transparent conductive layer 800 is formed of the compound including ZnO, for example, ZnOH, ZnO:B, or ZnO:Al, uniformity of the second transparent conductive layer 800 is improved more than uniformity of the second transparent conductive layer 800 which is formed of ITO. It can be identically applied to the first transparent conductive layer 400.

As shown in FIG. 5H, the second electrode 900 is formed on the second transparent conductive layer 800, thereby completing the solar cell.

The second electrode 900 may be formed of the metal material such as Ag, Al, Ag+Al, Ag+Mg, Ag+Mn, Ag+Sb, Ag+Zn, Ag+Mo, Ag+Ni, Ag+Cu, or Ag+Al+Zn by sputtering, or may be formed of paste of the above metal material by the above printing method.

The second electrode 900 may be formed on the entire surface of the second transparent conductive layer 800, or may be patterned so as to transmit the solar ray, as shown in FIG. 2.

From the above processes of FIGS. 5A to 5H, it is possible to omit any one of the process for forming the first auxiliary layer 300 and the process for forming the second auxiliary layer 700.

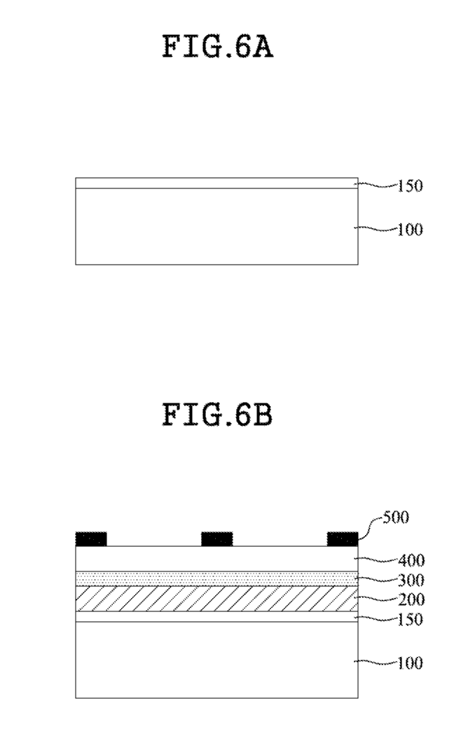

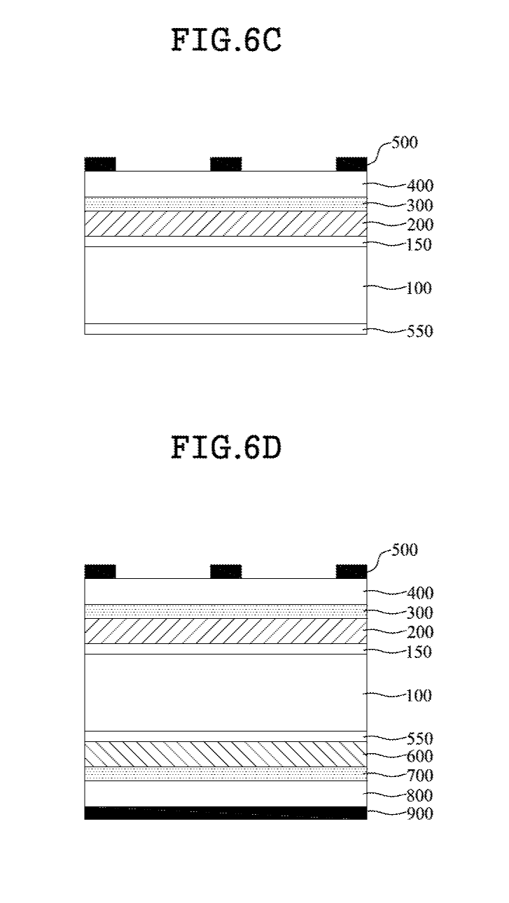

FIGS. 6A to 6D are cross section views illustrating a method for manufacturing a solar cell according to another embodiment of the present invention, which illustrate a method for manufacturing the solar cell according to the second embodiment of the present invention shown in FIG. 3. A detailed explanation for the same parts as those of the aforementioned embodiment will be omitted.

First, as shown in FIG. 6A, the first intrinsic semiconductor layer 150 is formed on the upper surface of the semiconductor wafer 100.

A process for forming the first intrinsic semiconductor layer 150 may comprise forming an I (intrinsic)-type amorphous silicon layer on the semiconductor wafer 100 by PECVD (Plasma Enhanced Chemical Vapor Deposition).

As shown in FIG. 6B, the first semiconductor layer 200 is formed on the first intrinsic semiconductor layer 150; the first auxiliary layer 300 is formed on the first semiconductor layer 200; the first transparent conductive layer 400 is formed on the first auxiliary layer 300; and the first electrode 500 is formed on the first transparent conductive layer 400.

As shown in FIG. 6C, the second intrinsic semiconductor layer 550 is formed on the lower surface of the semiconductor wafer 100.

A process for forming the second intrinsic semiconductor layer 550 may comprise forming an I (intrinsic)-type amorphous silicon layer on the semiconductor wafer 100 by PECVD (Plasma Enhanced Chemical Vapor Deposition).

As shown in FIG. 6D, the second semiconductor layer 600 is formed on the second intrinsic semiconductor layer 550; the second auxiliary layer 700 is formed on the second semiconductor layer 600; the second transparent conductive layer 800 is formed on the second auxiliary layer 700; and the second electrode 900 is formed on the second transparent conductive layer 800, thereby completing the solar cell.

From the above processes of FIGS. 6A to 6D, it is possible to omit any one of the process for forming the first auxiliary layer 300 and the process for forming the second auxiliary layer 700. Also, it is possible to omit any one of the process for forming the first intrinsic semiconductor layer 150 and the process for forming the second intrinsic semiconductor layer 550.

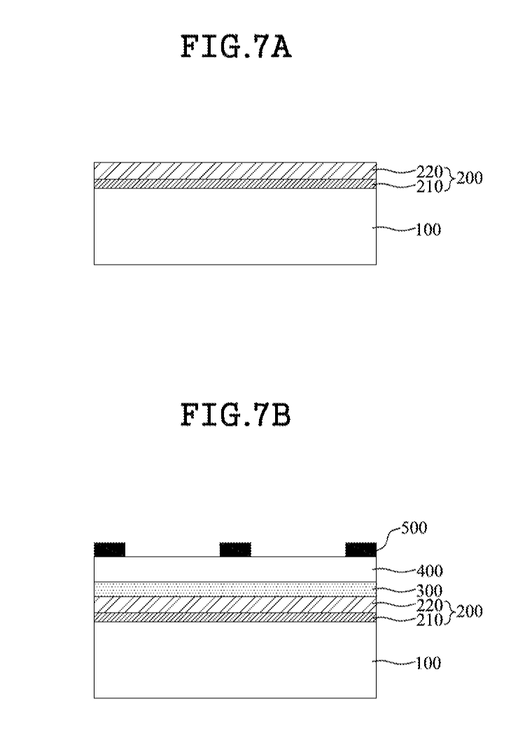

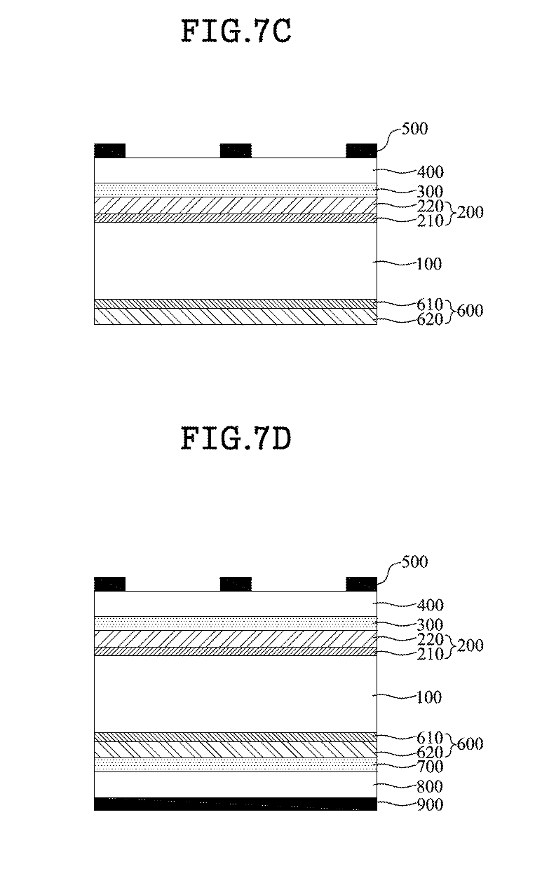

FIGS. 7A to 7D are cross section views illustrating a method for manufacturing a solar cell according to another embodiment of the present invention, which illustrate a method for manufacturing the solar cell according to the third embodiment of the present invention shown in FIG. 4. A detailed explanation for the same parts as those of the aforementioned embodiments will be omitted.

First, as shown in FIG. 7A, the first semiconductor layer 200 is formed on the upper surface of the semiconductor wafer 100.

A process for forming the first semiconductor layer 200 may comprise forming the first lightly-doped semiconductor layer 210 on the semiconductor wafer 100; and forming the first highly-doped semiconductor layer 220 on the firstly lightly-doped semiconductor layer 210.

Processes for forming the first lightly-doped semiconductor layer 210 and first highly-doped semiconductor layer 220 may be sequentially carried out inside one chamber. That is, the first semiconductor layer 210 with the lightly-doped P-type and the first semiconductor layer 220 with the highly-doped P-type may be sequentially formed by adjusting the input of dopant gas of group III elements such as boron (B) to the inside of one PECVD (Plasma Enhanced Chemical Vapor Deposition) chamber.

In more detail, for the process for producing the initial solar cell under the mass production method, a predetermined amount of B₂H₆ gas is supplied into the inside of the chamber, whereby the inside the chamber is prepared as the P-type dopant atmosphere. Then, SiH₄ and H₂ gas is supplied to the inside of the chamber, to thereby form the first semiconductor layer 210 with the lightly-doped P-type, and more particularly, the lightly-doped P-type amorphous silicon layer. Thereafter, SiH₄ and H₂ gas, together with B₂H₆ gas serving as the dopant gas, is supplied to the inside of the chamber, to thereby form the first semiconductor layer 220 with the highly-doped P-type, and more particularly, the highly-doped P-type amorphous silicon layer.

After completing the process for forming the first semiconductor layer 220 with the highly-doped P-type, B₂H₆ gas remains inside the chamber. Thus, when trying to manufacture the second solar cell after the initial solar cell, the inside of the chamber is maintained as the P-type dopant atmosphere. That is, the first semiconductor layer 210 with the lightly-doped P-type may be formed by supplying only SiH₄ and H₂ gas to the inside of the chamber without additional supply of B₂H₆ gas. Thereafter, SiH₄ and H₂ gas, together with B₂H₆ gas, is supplied to the inside of the chamber, to thereby form the first semiconductor layer 220 with the highly-doped P-type.

According to another embodiment of the present invention, the first semiconductor layer 210 with the lightly-doped P-type and the first semiconductor layer 220 with the highly-doped P-type are sequentially formed inside on chamber by adjusting the input of reaction gas to be supplied to the inside of one chamber, which enable to improve the productivity without the additional apparatus and complicated process.

Then, as shown in FIG. 7B, the first auxiliary layer 300 is formed on the first semiconductor layer 200; the first transparent conductive layer 400 is formed on the first auxiliary layer 300; and the first electrode 500 is formed on the first transparent conductive layer 400.

As shown in FIG. 7C, the second semiconductor layer 600 is formed on the lower surface of the semiconductor wafer 100.

A process for forming the second semiconductor layer 600 may comprise forming the second lightly-doped semiconductor layer 610 on the semiconductor wafer 100; and forming the second highly-doped semiconductor layer 620 on the second lightly-doped semiconductor layer 610.

Similarly to the first lightly-doped semiconductor layer 210 and first highly-doped semiconductor layer 220, the second lightly-doped semiconductor layer 610 and the second highly-doped semiconductor layer 620 may be sequentially formed inside one chamber. That is, the second semiconductor layer 610 with the lightly-doped N-type and the second semiconductor layer 620 with the highly-doped N-type may be sequentially formed by adjusting the input of dopant gas of group V elements such as phosphorus (P) to the inside of one PECVD (Plasma Enhanced Chemical Vapor Deposition) chamber.

In more detail, a predetermined amount of PH₃ gas is supplied into the inside of the chamber, whereby the inside the chamber is prepared as the N-type dopant atmosphere. Then, SiH₄ and H₂ gas is supplied to the inside of the chamber, to thereby form the second semiconductor layer 610 with the lightly-doped N-type. Thereafter, SiH₄ and H₂ gas, together with PH₃ gas serving as the dopant gas, is supplied to the inside of the chamber, to thereby form the second semiconductor layer 620 with the highly-doped N-type.

After completing the process for forming the second semiconductor layer 620 with the highly-doped N-type, PH₃ gas remains inside the chamber. Thus, when trying to manufacture the second solar cell after the initial solar cell, the inside of the chamber is maintained as the N-type dopant atmosphere. That is, the second semiconductor layer 610 with the lightly-doped N-type may be formed by supplying only SiH₄ and H₂ gas to the inside of the chamber without additional supply of PH₃ gas. Thereafter, SiH₄ and H₂ gas, together with PH₃ gas, is supplied to the inside of the chamber, to thereby form the second semiconductor layer 620 with the highly-doped N-type.

As shown in FIG. 7D, the second auxiliary layer 700 is formed on the second semiconductor layer 600; the second transparent conductive layer 800 is formed on the second auxiliary layer 700; and the second electrode 900 is formed on the second transparent conductive layer 800, to thereby complete the solar cell.

From the above processes of FIGS. 7A to 7D, it is possible to omit any one of the process for forming the first auxiliary layer 300 and the process for forming the second auxiliary layer 700. Also, it is possible to omit the step for forming the lightly-doped semiconductor layer in any one of the process for forming the first semiconductor layer 200 and the process for forming the second semiconductor layer 600.

For the above explanation of the manufacturing process, the first semiconductor layer 200, the first auxiliary layer 300, the first transparent conductive layer 400, and the first electrode 500 are sequentially formed on the upper surface of the semiconductor wafer 100; and then the second semiconductor layer 600, the second auxiliary layer 700, the second transparent conductive layer 800, and the second electrode 900 are sequentially formed on the lower surface of the semiconductor wafer 100. However, the method for manufacturing the solar cell according to the present invention may be variously changed in process.

For example, the first semiconductor layer 200 may be formed on the upper surface of the semiconductor wafer 100, and then second semiconductor layer 600 may be formed on the lower surface of the semiconductor wafer 100. Thereafter, the first auxiliary layer 300 is formed on the first semiconductor layer 200, and the second auxiliary layer 700 may be formed on the second semiconductor layer 600. Then, the first transparent conductive layer 400 may be formed on the first auxiliary layer 300, and the second transparent conductive layer 800 may be formed on the second auxiliary layer 700. After that, the first electrode 500 may be formed on the first transparent conductive layer 400, and the second electrode 900 may be formed on the second transparent conductive layer 800.

For the above explanation of the present invention, the semiconductor wafer 100 is formed of the N-type semiconductor wafer; the first semiconductor layer 200 is formed of the P-type semiconductor layer; and the second semiconductor layer 600 is formed of the N-type semiconductor layer, but it is not limited to this structure. The method for manufacturing the solar cell according to the present invention may be variously modified within the scope of satisfying the conditions of the PN junction structure, and the provision of the semiconductor wafer and the thin-film semiconductor layer. For example, if the semiconductor wafer 100 may be formed of the P-type semiconductor wafer, the first semiconductor layer 200 may be formed of the N-type semiconductor layer, and the second semiconductor layer 600 may be formed of the P-type semiconductor layer.

According to the solar cell of the present invention, the carrier generated in the semiconductor wafer 100 is collected in the first transparent conductive layer 400, and the collected carrier is drifted to the first electrode 500. Also, the carrier is collected in the second transparent conductive layer 800, and the collected carrier is drifted to the second electrode 900. Accordingly, the drift mobility of the carriers is relatively improved in comparison with the related art.

Especially, the first auxiliary layer 300 of the negative (−) polarity material to attract the hole is formed between the first semiconductor layer 200 and the first transparent conductive layer 400, and the second auxiliary layer 700 of the positive (+) polarity material to attract the electron is formed between the second semiconductor layer 600 and the second transparent conductive layer 800. Thus, the carrier generated in the semiconductor wafer 100 is easily drifted to the first transparent conductive layer 400 or the second transparent conductive layer 800, thereby improving the cell efficiency.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A solar cell comprising:
a semiconductor wafer having a first polarity;
a first semiconductor layer on a first surface of the semiconductor wafer;
a first transparent conductive layer on the first semiconductor layer;
a first electrode on the first transparent conductive layer;
a second semiconductor layer on a second surface of the semiconductor wafer opposite to the first surface, wherein the second semiconductor layer has a second polarity different from the first polarity;
a second transparent conductive layer on the second semiconductor layer;
a second electrode on the second transparent conductive layer; and
at least one of a first auxiliary layer and a second auxiliary layer, wherein the first auxiliary layer is between the first semiconductor layer and the first transparent conductive layer and improves drift of carriers from the semiconductor wafer to the first transparent conductive layer, and the second auxiliary layer is between the second semiconductor layer and the second transparent conductive layer, the auxiliary layer being adapted to improve drift of carriers from the semiconductor wafer to the second transparent conductive layer.

2. The solar cell according to claim 1, wherein the first auxiliary layer comprises a negative (−) polarity material layer to attract holes from the semiconductor wafer, and the second auxiliary layer comprises a positive (+) polarity material layer to attract electrons from the semiconductor wafer.

3. The solar cell according to claim 2, wherein the first auxiliary layer includes an oxygen-rich oxide, and the second auxiliary layer includes an oxygen-deficient oxide.

4. The solar cell according to claim 2, wherein the first auxiliary layer includes an oxide including one or more Group III elements, and the second auxiliary layer includes an oxide including one or more Group IV elements.

5. The solar cell according to claim 4, wherein the first auxiliary layer includes Al₂O₃, Ga₂O₃, or In₂O₃, and the second auxiliary layer includes SiOₓ, TiOₓ, ZrOₓ, or HfOₓ, where x is between 1 and 2.

6. The solar cell according to claim 2, wherein the first semiconductor layer comprises a P-type semiconductor layer, and the second semiconductor layer comprises an N-type semiconductor layer.

7. The solar cell according to claim 1, wherein at least one of the first and second semiconductor layers comprises a lightly-doped semiconductor layer on the semiconductor wafer, and a highly-doped semiconductor layer on the lightly-doped semiconductor layer.

8. The solar cell according to claim 1, further comprising an intrinsic semiconductor layer between the semiconductor wafer and at least one of the first semiconductor layer and the second semiconductor layer.

9. The solar cell according to claim 1, wherein at least one of the first and second transparent conductive layers comprises ZnO.

10. The solar cell according to claim 1, wherein the first electrode is in a first pattern so as to receive incident solar rays.

11. The solar cell according to claim 1, wherein a thickness of the first and second auxiliary layers is not more than 3 nm.

12. A method for manufacturing a solar cell comprising:
forming a first semiconductor layer on a first surface of a semiconductor wafer having a first polarity;
forming a first transparent conductive layer on the first semiconductor layer;
forming a first electrode on the first transparent conductive layer;
forming a second semiconductor layer on a second surface of the semiconductor wafer opposite to the first surface, wherein the second semiconductor layer has a second polarity different from the first polarity;
forming a second transparent conductive layer on the second semiconductor layer;
forming a second electrode on the second transparent conductive layer; and
forming at least one of a first auxiliary layer between the first semiconductor layer and the first transparent conductive layer and a second auxiliary layer between the second semiconductor layer and the second transparent conductive layer, the first auxiliary layer improving drift of carriers from the semiconductor wafer to the first transparent conductive layer, and the second auxiliary layer improving drift of carriers from the semiconductor wafer to the second transparent conductive layer.

13. The method according to claim 12, wherein forming the first auxiliary layer comprises forming an oxygen-rich oxide layer with a negative (−) polarity to attract holes from the semiconductor wafer, and
forming the second auxiliary layer comprises forming an oxygen-deficient oxide layer with a positive (+) polarity to attract electrons from the semiconductor wafer.

14. The method according to claim 13, wherein
the first semiconductor layer comprises a P-type semiconductor layer, and
the second semiconductor layer comprises an N-type semiconductor layer.

15. The method according to claim 12, further comprising an intrinsic semiconductor layer between the semiconductor wafer and either the first semiconductor layer or the second semiconductor layer.

16. The method according to claim 12, wherein forming at least one of the first and second semiconductor layers comprises:
forming a lightly-doped semiconductor layer on the semiconductor wafer; and
forming a highly-doped semiconductor layer on the lightly-doped semiconductor layer.

17. The method according to claim 16, wherein forming the lightly-doped semiconductor layer and forming the highly-doped semiconductor layer are carried out sequentially inside one chamber.

18. The method according to claim 17, wherein:
forming the lightly-doped semiconductor layer is carried out in an atmosphere comprising a first dopant, without supplying additional dopant to the chamber, and
forming the highly-doped semiconductor layer comprises supplying additional first dopant to the chamber.

19. The method according to claim 12, wherein at least one of forming the first transparent conductive layer and forming the second transparent conductive layer comprises forming ZnO by MOCVD (Metal Organic Chemical Vapor Deposition).
